(19) United States
(12) Patent Application Publication
(10) Pub. No.: US 2013/0077237 A1
(43) Pub. Date: Mar. 28, 2013

(54) ELECTRONIC DEVICE AND IMAGING DEVICE

(71) Applicant: PANASONIC CORPORATION, Osaka (JP)

(72) Inventors: NORIHITO KITAJIMA, Osaka (JP); SHUSAKU YAMAMOTO, Osaka (JP); TETSUYA MORI, Osaka (JP)

(73) Assignee: PANASONIC CORPORATION, Osaka (JP)

(21) Appl. No.: 13/621,506

(22) Filed: Sep. 17, 2012

(30) Foreign Application Priority Data
Sep. 22, 2011 (JP) 2011-206931

(51) Int. Cl. H05K 5/03

(52) U.S. Cl. 361/679.58

(57) ABSTRACT

An electronic device includes a housing, a slide cover and a restricting member. The housing includes a plate-like member. The plate-like member has a guide member protruding from an outer face of the plate-like member. The slide cover is disposed on the outer face of the plate-like member. The slide cover includes a slot-shaped guide rail guided by the guide member. The guide member is inserted into the guide rail. The restricting member is disposed on the outer face of the plate-like member. The restricting member is configured to restrict the position of the slide cover so as to maintain a state in which the guide member is inserted into the guide rail and the slide cover does not move away from the plate-like member.

### CROSS-REFERENCE TO RELATED APPLICATIONS

This application claims priority under 35 U.S.C. §119 to Japanese Patent Application No. 2011-206931, filed on Sep. 22, 2011. The entire disclosure of Japanese Patent Application No. 2011-206931 are hereby incorporated herein by reference.

### BACKGROUND

1. Technical Field

The technology disclosed herein relates to an imaging device and an electronic device comprising a slide cover.

2. Background Information

A digital camera known in the past comprised a front plate that constituted part of a housing, a lens fixed to the front plate, and a slide cover attached slidably in an opening formed in the front plate (see Japanese Laid-Open Patent Application 2010-210936). With the digital camera of Patent Literature 1, the lens could be exposed by sliding the slide cover.

### SUMMARY

A problem encountered with the conventional digital camera discussed in Japanese Laid-Open Patent Application 2010-210936 was difficulty in reducing the size of the device main body. More specifically, with a conventional digital camera, the slide cover was able to slide with respect to the front plate because of a structure in which the front plate was sandwiched between the slide cover and a hold-down plate disposed on the inside of the front plate, that is, in the interior of the device main body. With this structure, however, it was difficult to reduce the size of the device main body because the hold-down plate had to be disposed inside the device main body.

The technology disclosed herein was conceived in light of the above situation, and it is an object thereof to provide an electronic device and an imaging device with which it is easy to reduce the size of the device main body.

An electronic device disclosed herein includes a housing, a slide cover and a restricting member. The housing includes a plate-like member. The plate-like member has a guide member protruding from an outer face of the plate-like member. The slide cover is disposed on the outer face of the plate-like member. The slide cover includes a slot-shaped guide rail guided by the guide member. The guide member is inserted into the guide rail. The restricting member is disposed on the outer face of the plate-like member. The restricting member is configured to restrict the position of the slide cover so as to maintain a state in which the guide member is inserted into the guide rail and the slide cover does not move away from the plate-like member.

### BRIEF DESCRIPTION OF DRAWINGS

FIG. 1A is an oblique view of a digital camera;

FIG. 1B is an oblique view of a digital camera;

FIG. 2A is a front view of a digital camera;

FIG. 2B is a front view of a digital camera;

FIG. 3 is an exploded oblique view of a digital camera;

FIG. 4 is an exploded oblique view of a digital camera;

FIG. 5 is an exploded oblique view of a digital camera;

FIG. 6 is a cross section of a digital camera along the A-A line; and

FIG. 7 is a detail enlargement of FIG. 6.

### DETAILED DESCRIPTION OF EMBODIMENTS

An embodiment will now be described through reference to the drawings. In the description of the drawings below, those portions that are the same or similar will be given the same or similar numbers. These drawings are merely schematics representations, however, and the dimensional proportions and so forth may differ from those of the actual components. Therefore, the specific dimensions and so forth should be determined by referring to the following description. Of course, there are also portions in which the dimensional relation and proportions differ from one drawing to the next.

In the following embodiment, a digital camera will be described as an example of an electronic device equipped with a slide cover. In the following description, using a digital camera in its normal orientation (hereinafter also referred to as the landscape orientation) as a reference, the orientation facing the subject will be called “front,” that facing in the opposite direction from the subject will be called “rear,” a vertically upward orientation will be called “upper,” a vertically downward orientation will be called “lower,” to the right in a state of facing the subject directly will be called “right,” and to the left in a state of facing the subject directly will be called “left.” Also, in the following embodiment, a state in which the slide cover of the digital camera is open corresponds to the “power on state,” while a state in which the slide cover of the digital camera is closed corresponds to the “power off state.”

### Overall Configuration of Digital Camera 100

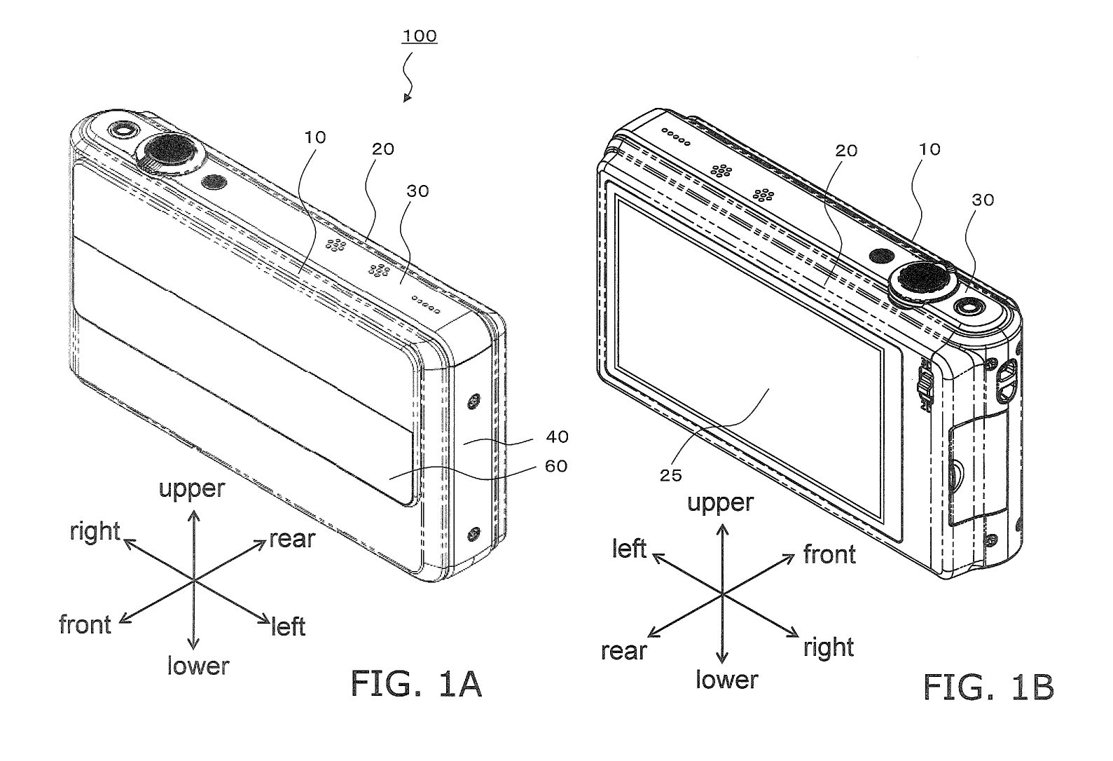

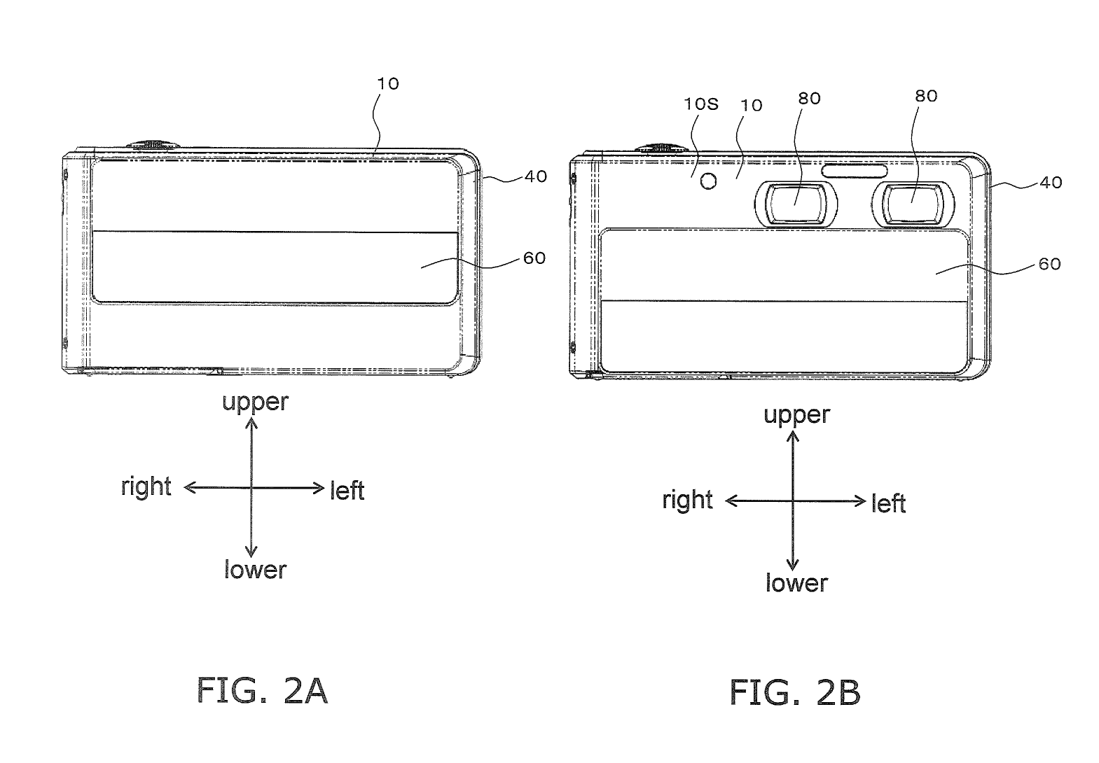

The overall configuration of the digital camera 100 pertaining to an embodiment will be described through reference to the drawings. FIG. 1A is an oblique view of the digital camera 100 pertaining to an embodiment, as seen from the front. FIG. 1B is an oblique view of the digital camera 100 pertaining to an embodiment, as seen from the rear. FIG. 2A is a front view of the digital camera 100 pertaining to an embodiment, when the power is off FIG. 2B is a front view of the digital camera 100 pertaining to an embodiment, when the power is on.

The digital camera 100 comprises a front plate 10 (an example of a “plate-like member”), a rear plate 20, a top plate 30, a side plate 40, a slide cover 60, a monitor 25, and lenses 80. The front plate 10, the rear plate 20, the top plate 30, and the side plate 40 constitute the “housing” pertaining to this embodiment.

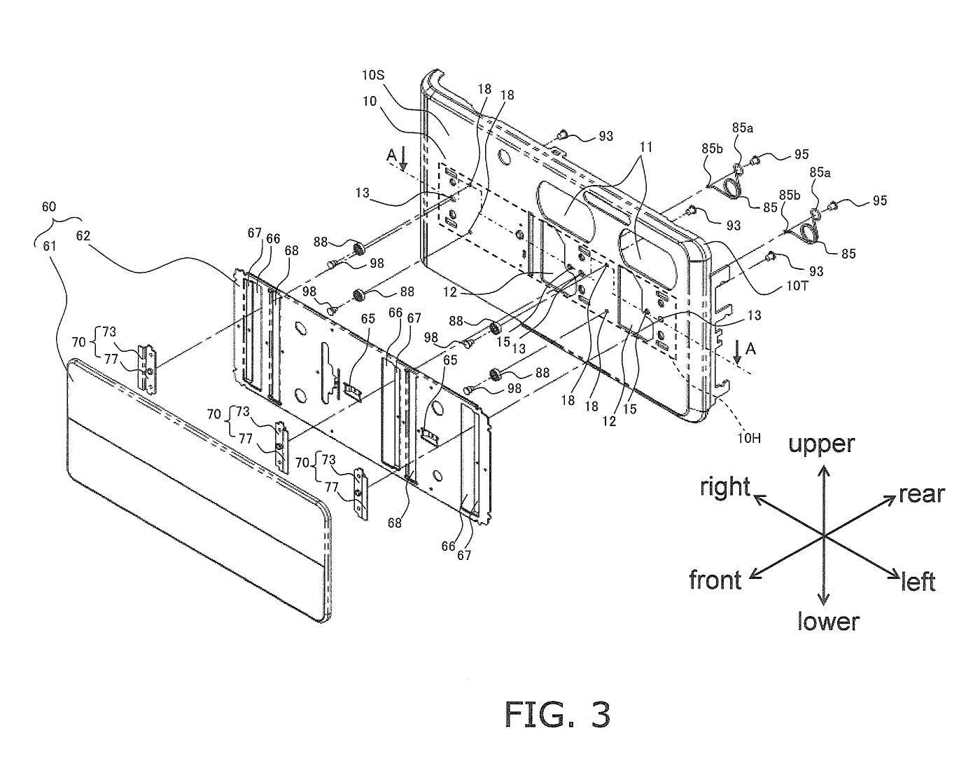

The front plate 10 constitutes a panel on the front side of the housing. The front plate 10 is disposed so that the plane with the largest surface area faces forward. The front plate 10 has an outer face 10S and an inner face 10T (see FIG. 3). The rear plate 20 constitutes a panel on the rear side of the housing. The top plate 30 constitutes a panel on the top side of the housing. The side plate 40 constitutes a panel on the left face of the housing. The right face of the housing is constituted by bending the right end of the front plate 10 and the right end of the rear plate 20 so that they curve inward. The slide cover 60 is attached to the front plate 10 slidably in the up and down direction. The slide cover 60 can be closed by sliding it upward, and opened by sliding it downward. The configuration of the slide cover 60 will be discussed below. The monitor 25 is fixed on the inside of the rear plate 20. The lenses 80 are disposed on the inner face 10T side of the front plate 10. The lenses 80 are covered by the slide cover 60 when the slide cover 60 is in its closed stated, and are exposed from the slide cover 60 when the slide cover 60 is in its open state.

### Configuration of Front Plate 10

The configuration of the front plate 10 pertaining to an embodiment will be described through reference to the drawings. FIG. 3 is an exploded oblique view of the area around the front plate 10 and the slide cover 60.

As shown in FIG. 3, the front plate 10 has an non-visible part 10H, a pair of lens openings 11, a pair of spring openings 12, three hold-down plate fixing holes 13, a pair of pin fixing holes 15, and two sets of shaft fixing holes 18.

The non-visible part 10H refers to a region of the front plate 10 that is hidden by the slide cover 60 both when the slide cover 60 is in its closed state and when it is in its open state, as viewed from the housing front face.

The lens openings 11 are formed above the non-visible part 10H. The lens openings 11 are formed in the upper-left portion of the front plate 10. The lenses 80 are attached to the lens openings 11. Light from the outside is incident on the lenses 80 through the lens openings 11.

The spring openings 12 are formed in the non-visible part 10H. The spring openings 12 have a shape such that attached centering springs 85 do not interfere with the front plate 10 when the slide cover 60 is in either its open state, its closed state, or its sliding state (hereinafter referred to as a transitional state).

The hold-down plate fixing holes 13 are formed at three places: near the center in the left and right direction of the non-visible part 10H, and on the left and right ends. The hold-down plate fixing holes 13 have a circular shape whose diameter is larger than the threaded part diameter of screws 93, and smaller than the head diameter of the screws 93.

The pin fixing holes 15 are formed inside the non-visible part 10H and near the spring openings 12. The pin fixing holes 15 have a circular shape whose diameter is larger than the flared part of pins 95, and smaller than the spring fixing part of the pins 95. The pins 95 are fixed in the pin fixing holes 15 by flaring the flared part inserted from the inner face 10T side.

The two sets of shaft fixing holes 18 are formed with each set comprising one hole at the top part and one at the bottom part of the non-visible part 10H, with the holes aligned in the up and down direction. One set of the shaft fixing holes 18 is formed at the left end of the non-visible part 10H, and one set at the right end, for a total of four holes. The two sets of shaft fixing holes 18 are disposed parallel to one another. The shaft fixing holes 18 have a circular shape whose diameter is larger than the flared part of shafts 98, and smaller than the roller fixing part of the shafts 98. In a state of having been inserted into rollers 88 (an example of guide members), the shafts 98 are fixed in the shaft fixing holes 18 by flaring the flared part inserted from the outer face 10S side.

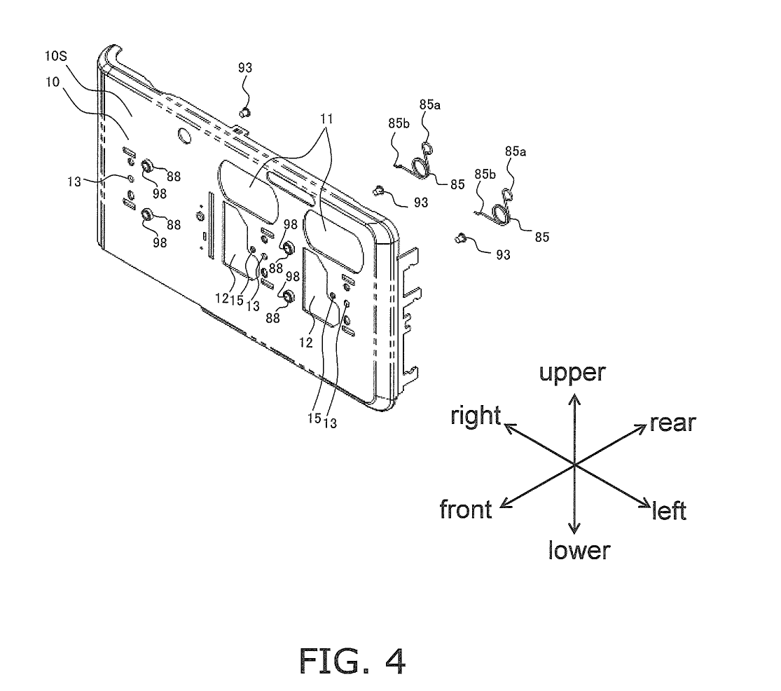

FIG. 4 shows the state when the rollers 88 have been fixed to the front plate 10 by the shafts 98. As shown in FIG. 4, the shafts 98 are fixed perpendicular to the outer face 10S of the front plate 10. The shafts 98 are the rotational shafts of the rollers 88. Specifically, the rollers 88 are disposed so as to protrude on the outer face 10S side, and are provided to the outer face 10S rotatably, with the rotational axis being a direction perpendicular to the outer face 10S.

### Configuration of Slide Cover 60

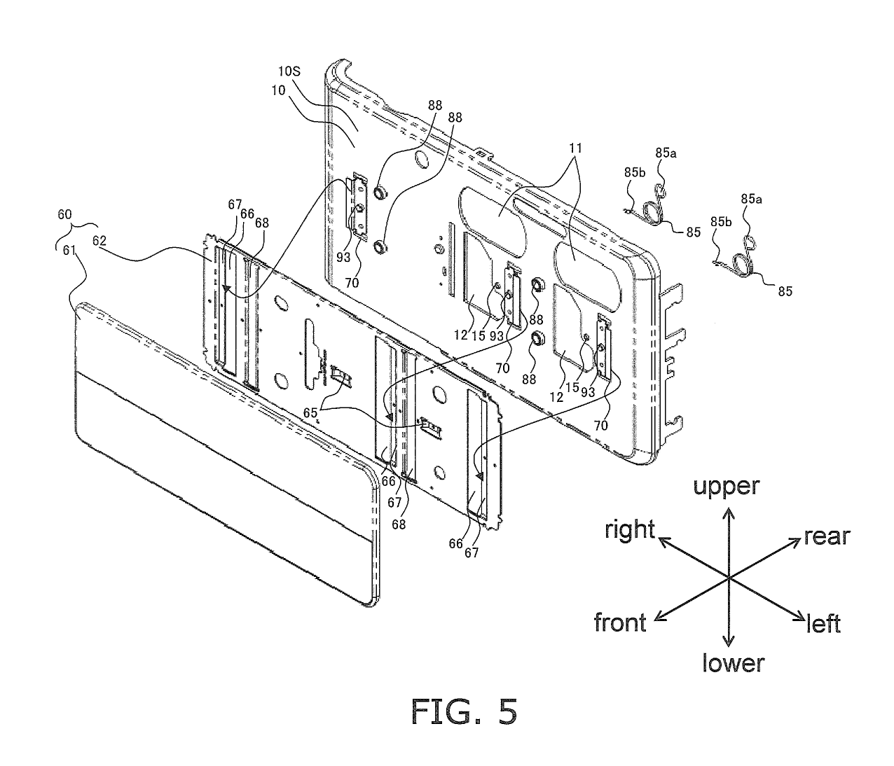

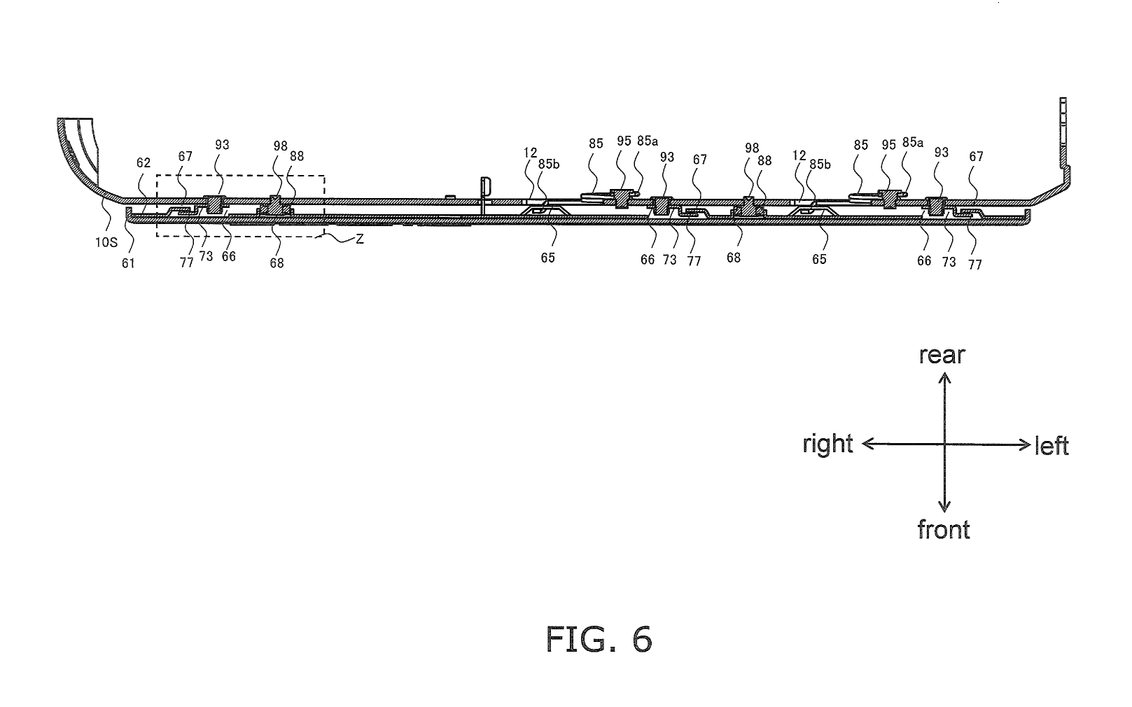

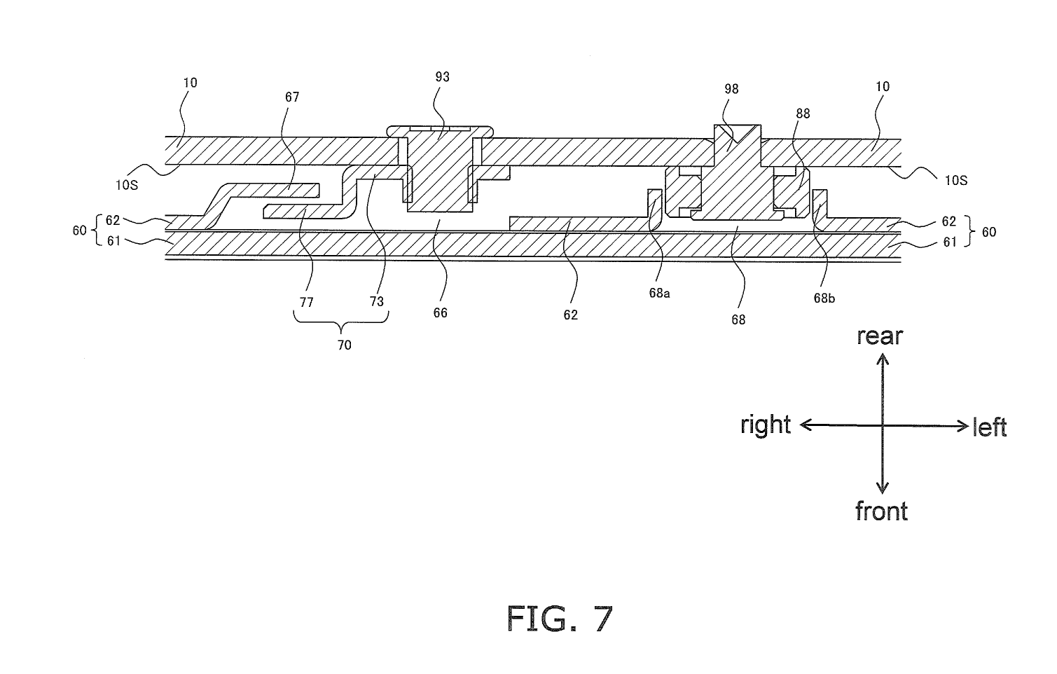

The configuration of the slide cover 60 pertaining to an embodiment will be described through reference to the drawings. FIG. 5 shows the state when hold-down plates 70 have been fixed to the front plate 10 with the screws 93. FIG. 6 is a cross section along the A-A line, showing the area around the slide cover 60 and the front plate 10 of the front plate digital camera 100 pertaining to an embodiment. FIG. 7 is a detail view of the region Z surrounded by a broken line in FIG. 6. For the sake of convenience, a state in which a plate 62 has not been attached is shown in FIG. 5. FIG. 3 will be referred to as needed in the following description.

As shown in FIG. 3, the slide cover 60 comprises a cover component 61 and the plate 62. The plate 62 is disposed parallel to the front plate 10 between the cover component 61 and the outer face 10S. The plate 62 is a rectangular plate-like member whose external shape is smaller than that of the cover component 61. The plate 62 has a pair of spring fixing holes 65, three openings 66, three receivers 67, and a pair of guide holes 68 (an example of guide rails).

The spring fixing holes 65 are formed so as to be opposite the spring openings 12 in the front plate 10 near the center of the plate 62 in the up and down direction. The spring fixing holes 65 have a circular shape whose diameter is larger than the wire diameter of the centering springs 85. The ends 85a of the centering springs 85 are fixed to the pins 95. The centering springs 85 impart a biasing force to the cover component 61 when the user slides the cover component 61 up and down. Specifically, it biases the slide cover 60 toward its open state (downward) when the slide cover 60 is at a position in between the open and closes states, but closer to the open state. It also biases the slide cover 60 toward its closed state (upward) when at a position closer to the closed state.

The openings 66 are formed so as to be opposite the hold-down plate fixing holes 13 of the front plate 10, at three places: near the center in the left and right direction of the plate 62, and on the left and right ends. The openings 66 have a rectangular shape extending in the up and down direction. The openings 66 have a shape that does not interfere with the hold-down plates 70 fixed to the outer face 10S in the open state, closed state, or transitional state of the slide cover 60.

The receivers 67 are formed at positions adjacent in the left and right direction, for each of the three openings 66. The receivers 67 are formed on the right side of the opening 66 on the right end, and on the left side of the openings 66 in the middle and on the left end. As shown in FIG. 7, the receivers 67 have a rectangular shape in plan view that is parallel to the plate 62. The receivers 67 are formed so as to extend up and down along the lengthwise direction of the openings 66.

The guide holes 68 are formed in a slot shape at two places: the left and right ends of the plate 62. One of the two guide holes 68 is formed near the left side of the receiver 67 and the opening 66 at the right end. This guide hole 68 is formed in the up and down direction so as to be opposite the set of shaft fixing holes 18 at the right end. The other guide hole 68 is formed near the left side of the receiver 67 and the opening 66 in the middle. This guide hole 68 is formed in the up and down direction so as to be opposite the set of shaft fixing holes 18 on the left end. The guide holes 68 have a rectangular shape that extends in the up and down direction, with the length of a short side being greater than the diameter of the rollers 88.

As shown in FIG. 7, guides 68a and 68b that are bent toward the rear and at a right angle to the surface of the plate 62 are provided along the two long sides of the guide holes 68. The guide holes 68 at two places are disposed parallel to each other, and when the front plate 10 and the slide cover 60 are attached, the two sets of rollers 88 are inserted into the guide holes 68 at the two places. Here, the rollers 88 can come into contact with either the guide 68a or the guide 68b. Also, in a state in which the front plate 10 and the slide cover 60 have been attached, when the slide cover 60 is in its closed state, the lower rollers of the two sets of rollers 88 come into contact with the lower ends of the guide holes 68. When the slide cover 60 is in its open state, the upper rollers of the two sets of rollers 88 come into contact with the upper ends of the guide holes 68.

The guide holes 68 and the rollers 88 are preferably disposed at positions that do not overlap the positions of the lens openings 11 in the left and right direction. This is for the following reason. When the slide cover 60 moves up and down, if it is forcefully pressed and bent from the front toward the front plate 10, there is the possibility that the guides 68a and 68b that are bent to the rear will touch the front plate 10. Even if this happens, with the layout discussed above, the lenses 80 exposed from the lens openings 11 (or the cover glass used to protect the lenses 80, etc.) will not be scratched, so there will be no effect on the captured image.

The movement of the plate 62 is restricted by the hold-down plates 70 in the forward and backward direction so as not to move away from the front plate 10. The hold-down plates 70 (an example of restricting members) each have a fixed component 73 and a hold-down component 77. The fixed component 73 is a plate-like member having a rectangular shape. The fixed component 73 is tapped for screw fastening. As shown in FIG. 7, the fixed component 73 is fixed to the outer face 10S by a screw 93 that passes from the inner face 10T side through the hold-down plate fixing hole 13. The hold-down component 77 is a plate-like member with a rectangular shape, disposed parallel to, but on a different level from, the fixed component 73. The receiver 67 is disposed between the hold-down component 77 and the outer face 105. With this configuration, movement of the receiver 67 of the plate 62 is restricted by the hold-down component 77 in the forward and backward direction, but its movement in the up and down direction is not restricted. Specifically, the hold-down plates 70 are latched in the openings 66 so as to be able to move along the long sides of the openings 66. Therefore, the plate 62 can slide parallel to the up and down direction without moving away from the front plate 10.

The cover component 61 is a rectangular plate-like member disposed on the plate 62 of the front plate 10. The cover component 61 is fixed to the plate 62 by double-sided tape.

### Operation of Slide Cover 60

The operation of the slide cover 60 pertaining to an embodiment will be described through reference to the drawings.

As discussed above, when the slide cover 60 is in its closed state, the slide cover 60 is disposed at the upper part of the housing. At this point, the centering springs 85 bias the slide cover 60 upward. As a result, the lower rollers of the two sets of rollers 88 maintain a state of contact with the lower ends of the guide holes 68, that is, a closed state. When the user applies downward force to the cover component 61, force is exerted on the slide cover 60 in various directions, depending on the orientation of the force and the position where the force was applied. However, the receivers 67 are restricted by the hold-down components 77 and the outer face 10S with respect to force in the forward and backward direction. The rollers 88 are restricted by the guides 68a and 68b with respect to force in the left and right direction. Thus, movement of the slide cover 60 is limited to just the up and down direction of the housing, regardless of the position or orientation of the force applied by the user. Also, even if the rollers 88 come into contact with the guides 68a or the guides 68b during sliding, the rotation of the rollers 88 will allow the slide cover 60 to slide smoothly.

The result of this downward sliding of the slide cover 60 is that the upper rollers of the two sets of rollers 88 hit the upper ends of the guide holes 68 and are in an open state, and movement of the slide cover 60 stops. The centering springs 85 at this point bias the slide cover 60 downward. As a result, the upper rollers of the two sets of rollers 88 maintain an open state in which they are in contact with the upper ends of the guide holes 68.

The same applies when the slide cover 60 moves from its open state to its closed state.

### Action and Effect

(1) The digital camera 100 pertaining to an embodiment comprises a housing that includes the front plate 10 having guide members that protrude on the outer face 10S side, the slide cover 60 that is disposed on the outer face 10S side of the front plate 10 and has the slot-shaped guide holes 68 guided by the inserted guide members, and the hold-down plates 70 that are disposed on the outer face 10S side of the front plate 10 and restrict the position of the slide cover 60 so as to maintain a state in which the guide members are inserted into the guide holes 68 and so that the slide cover 60 does not move away from the front plate 10.

With this configuration, the mechanism for slidably fixing the slide cover 60, namely, the guide members, the guide holes 68, the hold-down plates 70, etc., is constituted in front of the front plate 10, that is, outside of the housing, so fewer parts have to be held in the housing, and the thickness of the housing in the forward and backward direction can be reduced by a corresponding amount. Therefore, an electronic device can be provided with which it is easy to reduce the size of the housing. Also, since the guide members can be fixed directly to the front plate 10, without any frames or the like inside the housing, the number of parts can be reduced.

(2) With the digital camera 100 pertaining to an embodiment, the guide members are the rollers 88 provided rotatably around a rotational axis that is perpendicular to the outer face 10S of the front plate 10, and the guide holes 68 comprise the guides 68a and 68b that come into contact with the rollers 88.

With this configuration, when the slide cover 60 slides, no matter how the user applies force to the slide cover 60, the guide 68a or the guide 68b will come into contact with the rollers 88, and the rollers 88 will rotate, allowing the slide cover 60 to slide smoothly.

### Other Embodiments

The present invention was described by giving an embodiment above, but the text and drawings that make up part of this disclosure should not be construed as limiting this invention. Various substitute embodiments, working examples, and application techniques will probably be obvious to a person skilled in the art from this disclosure.

(A) In the above embodiment, a configuration was described in which the rollers 88 were inserted into the guide holes 68, and the rollers 88 moved relatively along the guide holes 68, and this allowed the slide cover 60 to slide, but this is not the only option. For example, guide pins may be provided instead of the rollers 88 and the shafts 98.

(B) In the above embodiment, the front plate 10 was described as an example of a “plate-like member,” but this is not the only option. The rear plate 20, the top plate 30, and the side plate 40 are other examples of a “plate-like member.”

(C) In the above embodiment, the digital camera 100 was described as an example of an “electronic device,” but this is not the only option. A video camera, a portable telephone, and an IC recorder are other examples of an “electronic device.”

Thus, the present invention naturally includes various embodiments and so forth not discussed herein. Therefore, the technological scope of the present invention is determined only by the invention-defining matter pertaining to the appropriate patent claims from the above description.

What is claimed is:

1. An electronic device comprising:
a housing including a plate-like member, the plate-like member having a guide member configured to protrude from an outer face of the plate-like member;
a slide cover disposed on the outer face of the plate-like member, the slide cover including a slot-shaped guide rail configured to be guided by the guide member, the guide member inserted into the guide rail; and
a restricting member disposed on the outer face of the plate-like member, the restricting member configured to restrict a position of the slide cover so as to maintain a state in which the guide member is inserted into the guide rail and the slide cover does not move away from the plate-like member.

2. The electronic device according to claim 1, wherein
the guide member is a roller configured to rotate about a rotational axis perpendicular to the outer face of the plate-like member, and
the guide rail has a roller receiver configured to contact the roller.

3. The electronic device according to claim 1, wherein
the slide cover has an opening formed along the guide rail, and
the restricting member is latched in the opening so that the restricting member is configured to be movable along a long side of the opening.

4. The electronic device according to claim 2, wherein
the slide cover has an opening formed along the guide rail, and
the restricting member is latched in the opening so that the restricting member is configured to be movable along a long side of the opening.

5. An imaging device comprising:
a housing including a plate-like member, the plate-like member having a guide member configured to protrude from an outer face of the plate-like member;
a lens attached to the housing;
a slide cover disposed on the outer face of the plate-like member, the slide cover including a slot-shaped guide rail configured to be guided by the guide member, the guide member inserted into the guide rail; and
a restricting member disposed on the outer face of the plate-like member, the restricting member configured to restrict a position of the slide cover so as to maintain a state in which the guide member is inserted into the guide rail and the slide cover does not move away from the plate-like member.

6. The imaging device according to claim 5, wherein
the guide member is a roller configured to rotate about a rotational axis perpendicular to the outer face of the plate-like member, and
the guide rail has a roller receiver configured to contact the roller.
